(19) United States
(12) Patent Application Publication
(10) Pub. No.: US 2009/0094173 A1
(43) Pub. Date: Apr. 9, 2009

(54) Intelligent Power Unit, and Applications Thereof

(75) Inventors: Rodney G. SMITH, Boca Raton, FL (US); Ludmilla D. Werbos, Arlington, VA (US); Paul J. Werbos, Arlington, VA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Adaptive Logic Control, LLC, Washington, DC (US)

(21) Appl. No.: 11/868,169

(22) Filed: Oct. 5, 2007

(51) Int. Cl. G01R 11/56

(52) U.S. Cl. 705/412

(57) ABSTRACT

The present invention provides an intelligent power unit, and applications thereof. In an embodiment, the intelligent power unit includes a battery, a power switch, and a control unit. The control unit receives price information and operates the power switch based on the price information to charge the battery during periods of relatively low electrical energy prices. During periods of relatively high electrical energy prices, the control unit cause the energy stored in the battery to be used to power attached loads. The price information provided to the control unit can be actual price information regarding the cost to generate electrical power, estimated price information, or contract price information. It is a feature of the intelligent power unit of the present invention that it can be used to shift a utility's electrical power demand in time.

### FIELD OF THE INVENTION

The present invention generally relates to energy management. More particularly, it relates to an intelligent power unit, and applications thereof.

### BACKGROUND OF THE INVENTION

Electricity and the power network used to transmit and distribute it are vital. Deregulation and shifting power flows, however, are forcing the power network to operate in ways it was never intended. In the United States, for example, the number of desired power transactions that cannot be implemented due to transmission bottlenecks continues to increase each year. This trend, along with a trend of increased electric power demand, has pushed the capacity of many transmission lines to their design limits. In some regions, the increase in electric power demand is such that periods of peak demand are dangerously close to exceeding the maximum supply levels that the electrical power industry can generate and transmit.

What are needed are new systems, methods, and apparatuses that allow the power network to be operated in a more cost effective and reliable manner.

### BRIEF SUMMARY OF THE INVENTION

The present invention provides an intelligent power unit, and applications thereof. In an embodiment, the intelligent power unit includes a battery, a power switch, and a control unit. The control unit receives price information and operates the power switch based on the price information to charge the battery during periods of relatively low electrical energy prices. During periods of relatively high electrical energy prices, the control unit cause the energy stored in the battery to be used to power attached loads. The price information provided to the control unit can be actual price information regarding the cost to generate electrical power, estimated price information, or contract price information. It is a feature of the intelligent power unit of the present invention that it can be used to shift a utility's electrical power demand in time and thus present opportunities to substantially reduce the cost paid for peak load power as well as reduce congestion of transmission facilities.

Further embodiments, features, and advantages of the present invention, as well as the structure and operation of the various embodiments of the present invention, are described in detail below with reference to the accompanying drawings.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 is a diagram that illustrates an example power network.

FIG. 2 is a diagram that illustrates using an intelligent power unit to power various household loads.

FIG. 3A is a diagram that illustrates an intelligent power unit that operates using electricity price information received from a smart utility meter.

FIG. 3B is a diagram that illustrates an intelligent power unit that operates using electricity price information received from a computer connected, for example, to the Internet.

FIG. 3C is a diagram that illustrates an intelligent power unit that operates using programmed electricity price information entered, for example, using a keypad unit.

FIG. 4A is a diagram that illustrates an example regional load profile for a weekday.

FIG. 4B is a diagram that illustrates how a utility's load is shifted in time using intelligent power units.

FIG. 5 is a diagram that illustrates an example intelligent power controller of an intelligent power unit.

FIG. 6A is a diagram that illustrates a first example of how load information is provided to an intelligent power controller of an intelligent power unit.

FIG. 6B is a diagram that illustrates a second example of how load information is provided to an intelligent power controller of an intelligent power unit.

FIG. 7 is a diagram that illustrates an example of how environmental information is provided to an intelligent power controller of an intelligent power unit.

FIG. 8 is a diagram that illustrates an example of how programmable price information is generated in an intelligent power controller of an intelligent power unit.

FIG. 9 is a diagram that illustrates an example of how a load scheduler of an intelligent power unit operates.

FIG. 10 is a diagram that illustrates example information stored by an intelligent power controller of an intelligent power unit.

FIG. 11 is a diagram that illustrates an example central control unit of an intelligent power controller of an intelligent power unit.

FIG. 12 is a diagram that illustrates an example prediction module of a central control unit of an intelligent power controller of an intelligent power unit.

FIG. 13 is a diagram that illustrates an example training circuit for a prediction module of a central control unit of an intelligent power controller of an intelligent power unit.

FIG. 14 is a diagram that illustrates using an intelligent power unit with solar energy panels.

FIG. 15 is a diagram that illustrates using an intelligent power unit with a windmill.

The present invention is described with reference to the accompanying drawings. The drawing in which an element first appears is typically indicated by the leftmost digit or digits in the corresponding reference number.

### DETAILED DESCRIPTION OF THE INVENTION

The present invention provides an intelligent power unit, and applications thereof. In the detailed description of the invention herein, references to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

In an embodiment, an intelligent power unit according to the present invention includes a battery, a power switch, and a control unit. The control unit receives price information and operates the power switch based on the price information to charge the battery during periods of relatively low electrical energy prices. During periods of relatively high electrical energy prices, the control unit cause the energy stored in the battery to be used to power attached loads. The price information provided to the control unit can be actual price information regarding the cost to generate electrical power, estimated price information, or contract price information.

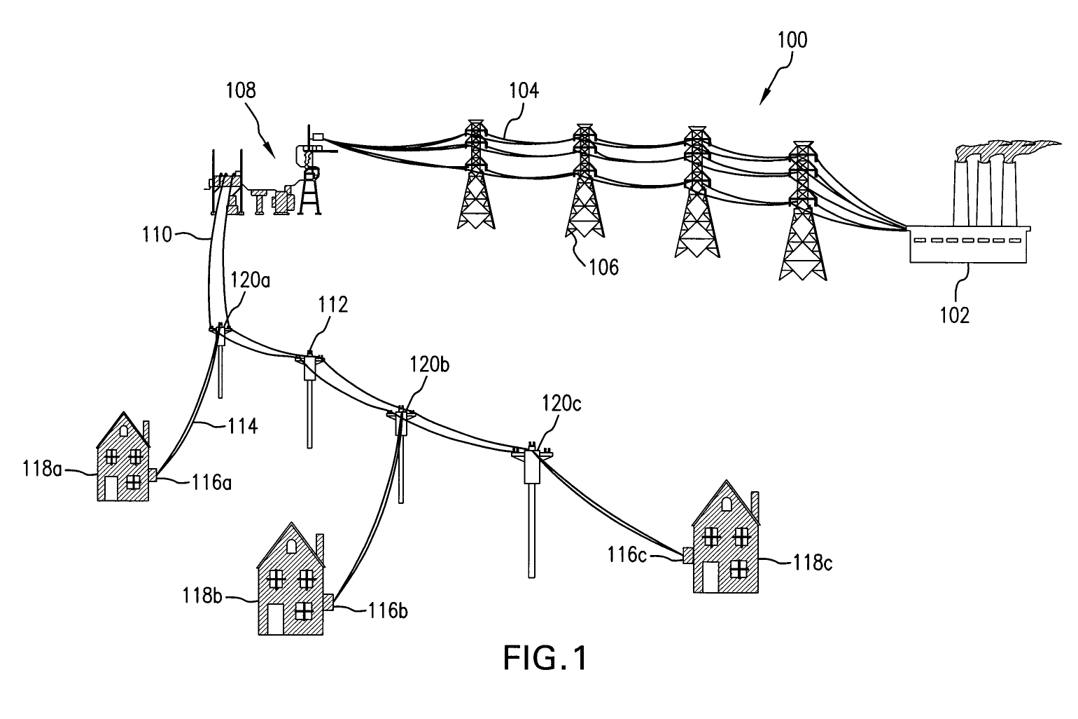

FIG. 1 is a diagram that illustrates an example power network 100. Power network 100 illustrates how electrical power from one or more generating plants 102 is delivered to customers residing, for example, in houses 118a-c. The electrical power is transmitted from generating plant 102 to a substation 108 using high voltage transmission lines 104 supported by towers 106. At substation 108, the voltage of the electrical power is reduced and the electrical power is distributed to transformers 120a-c near houses 118a-c. The electrical power is distributed from substation 108 using distribution lines 110 supported by poles 112. At transformers 120a-c, the voltage of the electrical power is further reduced before being supplied to houses 118a-c. Electrical meters 116a-c are used to monitor the amount of electrical energy supplied to houses 118a-c.

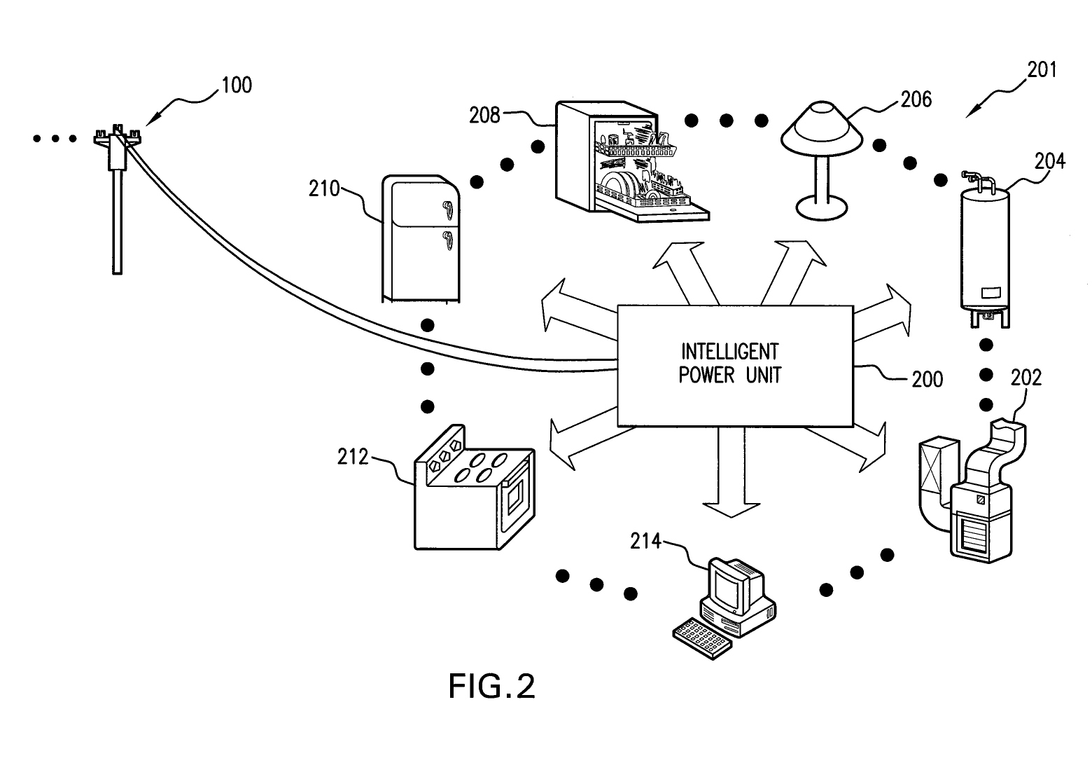

FIG. 2 is a diagram that illustrates an intelligent power unit 200 powering various household loads according to an embodiment of the present invention. These loads include a heating and air conditioning (HVAC) unit 202, a hot water heater 204, lighting fixtures 206, a dishwasher 208, a refrigerator 210, a stove 212, electronic devices such as, for example, a computer 214, etc. As described in more detail below, intelligent power unit 200 is used, for example, to time-shift the electrical loads of residential customer by storing electrical energy distributed over power network 100 when the electrical power being generated is relatively inexpensive (e.g., during off-peak hours) and by supplying stored electrical energy to household loads when the electrical power being generated and distributed over power network 100 is relatively expensive (e.g., during periods of peak load). By shifting electrical loads in time, intelligent power unit 200 greatly benefit an electrical utility (e.g., by flattening the utility's power demand curve and by reducing transmission congestion). In addition, intelligent power unit 200 also benefit the customer, for example, by allowing the customer to buy and store electrical energy when it is relatively inexpensive and to use stored electrical energy during periods when electrical power from power network 100 is relatively expensive or temporarily interrupted, thereby reducing the customer's electricity bills and improving the customer's quality of power.

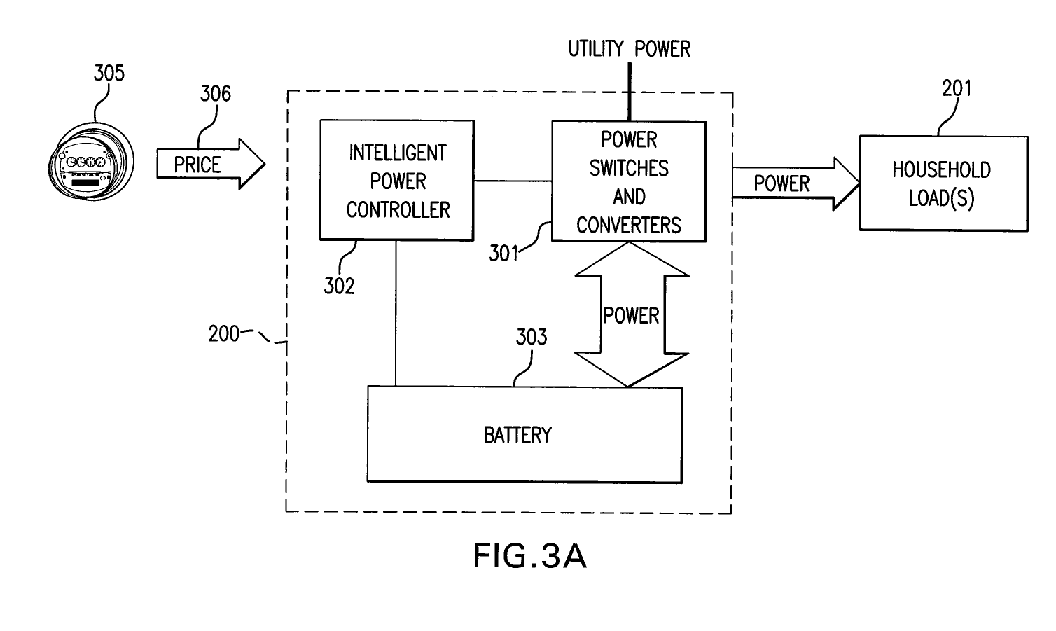

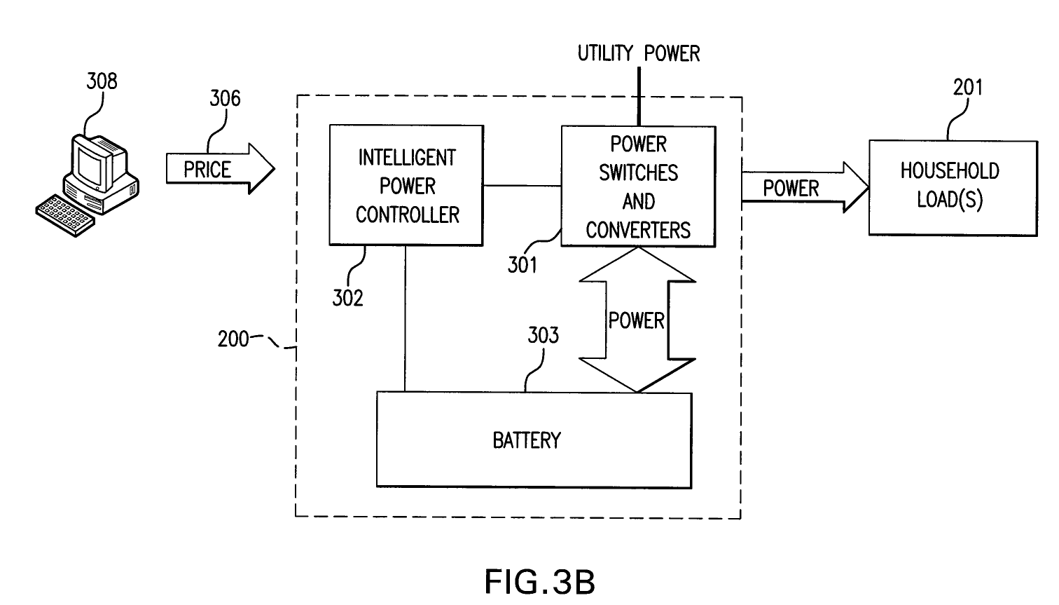

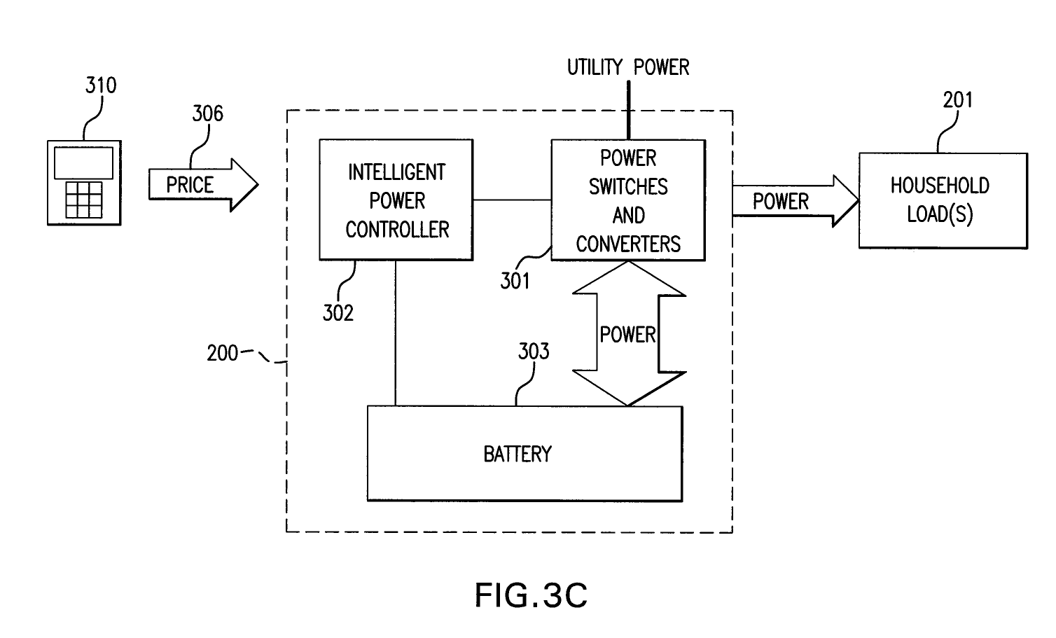

FIG. 3A is a diagram that further illustrates intelligent power unit 200 according to an embodiment of the present invention. As shown in FIG. 3A, intelligent power unit 200 includes power switches and converters 301 (also referred to herein collectively as a power switch), an intelligent power controller 302, and a battery 303.

In operation, power switch and converters 301 are used to supply utility power to household load(s) 201 and/or battery 303. When utility power is being supplied to battery 303, it is converted, for example, from ac power to dc power by a rectifier. Power switches and converters 301 are also used to supply power from battery 303 to household load(s) 201 and/or to sell power back to a utility. Power supplied from battery 303 is converted, for example, from dc power to ac power of an appropriate voltage by an inverter. In an embodiment, an intelligent power unit 200 can also be configured to supply dc power. Each of the converters used by intelligent power unit 200 can be any suitable commercially available rectifier, inverter and/or converter.

Intelligent power controller 302 monitors and controls operation of power switches and converters 301 and battery 303. As shown in FIG. 3A, in an embodiment, when used in conjunction with a smart electrical meter 305, intelligent power controller 302 receives price information 306 from the smart electrical meter. This price information is used by intelligent power controller 302 to determine when electrical energy supplied by a utility should be stored in battery 303 (e.g., when the price of electrical power is relatively low). The price information is also used by intelligent power controller 302 to determine when electrical energy stored in battery 303 should be supplied to household load(s) 201 and/or sold back to a utility (e.g., when the price of electrical power is relatively high). Intelligent power controller 302 is described in more detail below.

Battery 303 can be any type of battery suitable for multiple charging and discharging cycles. Battery 303 is preferably sized to supply all of the electrical needs of a typical home for several hours (e.g., the time frame of a utility's peak electrical load). Suitable batteries include, for example, the Thunder Sky lithium-ion batteries, which are available from Thunder Sky Energy Group Limited, whose address is Thunder Sky Industrial Base, No. 3 Industrial Zone, Lisonglang Village, Gongming Town, Bao'an District, Shenzhen, P.R.C, 5181016 (http://www.thunder-sky.com). Other batteries are also suitable and can be used.

FIG. 3B is a diagram that illustrates an intelligent power unit 200 that is used in conjunction with a computer 308 to receive price information 306. In an embodiment, intelligent power controller 302 of intelligent power unit 200 communications with computer 308, for example, using a home network. Computer 308 retrieves price information 306 by downloading it using the Internet and sends price information 306 to intelligent power controller 302. Intelligent power controller 302 uses the received price information to determine when electrical energy supplied by a utility should be stored in battery 303 and when electrical energy stored in battery 303 should be supplied to household load(s) 201 and/or sold back to the utility.

In an embodiment, the price information supplied by computer 308 is actual price information (e.g., price information that is periodically updated on-line throughout the course of a day as the actual price of generating electricity changes and provided in near real-time via the Internet to intelligent power controller 302). In another embodiment, the price information supplied from computer 308 is estimated price information (e.g., estimated price information that is generated by utilities and provided one or more times a day via the internet to intelligent power controller 302). In one embodiment, the price information represents electricity contract price information that encourages customers to buy and store electrical energy during off-peak hours of the day and to use the stored electrical energy during peak hours of the day. As noted herein, price information 306 (whether actual price information, estimated price information, or contract price information) is used by intelligent power controller 302 to make decisions about when electrical energy supplied by a utility should be stored in battery 303 and when electrical energy stored in battery 303 should be supplied to household load(s) 201 and/or sold back to a utility.

FIG. 3C is a diagram that illustrates an intelligent power unit 200 that is used in conjunction with a keypad unit 310 to receive price information 306. In an embodiment, keypad unit 310 is a part of intelligent power unit 200 that is used to enter/program price information 306 into a memory of intelligent power controller 302. The entered/programmed price information can be contract price information (e.g., in a case where the customer enters into a contract with a utility to buy power at specified prices during specified time periods). Using keypad unit 310, the entered/programmed price information can be updated or changed as necessary (e.g., when the customer enters into a new contract).

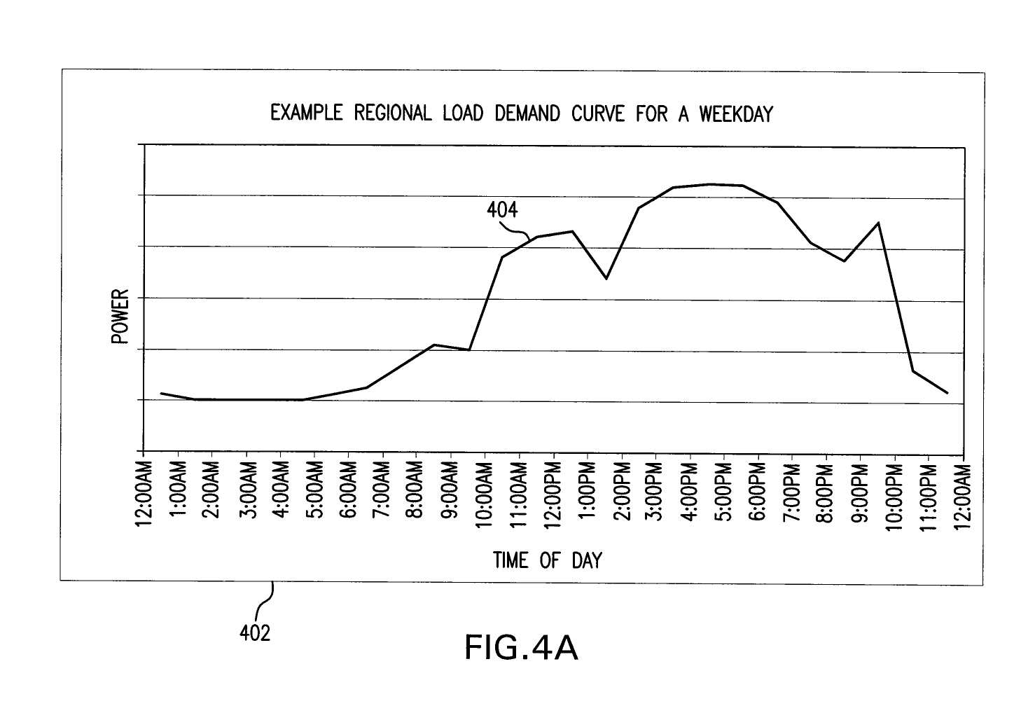

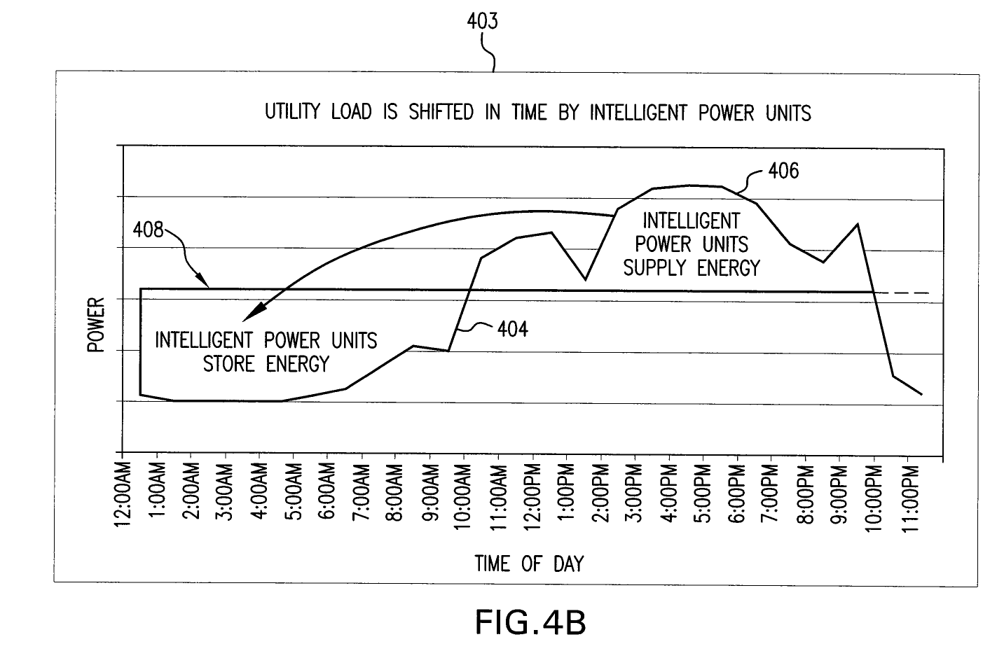

FIG. 4A is a chart 402 that illustrates an example regional load demand curve 404 for a weekday. The regional power demand curve 404 has three peaks: one around 12:00 PM; one between 3:00 PM and 6:00 PM; and one around 9:30 PM. As shown in chart 402, the regional power demand is lowest between 11:00 PM and about 5:00 AM.

FIG. 4B is a chart 403 that illustrates how the periods of peak load 406 of load curve 404 are shifted in time to the period of low load 408 using intelligent power units 200. As shown in chart 403, during the period of low power demand 408, intelligent power units 200 store electrical energy in their batteries. As a result, the utility's power demand is increased above that represented by curve 404. During the periods of high power demand 406, intelligent power units 200 supply electrical energy stored in their batteries to household loads and thereby reduce the utility's power demand represented by curve 404. Because the peak loads represented by curve 406 are reduced by the intelligent power units, the utility can avoid starting up and running expensive, inefficient and/or certain polluting generating units that would otherwise be needed to meet the peak load demands. In addition, the use of intelligent power units 200 can delay and/or eliminate the need to build additional generating units and their associate transmission lines.

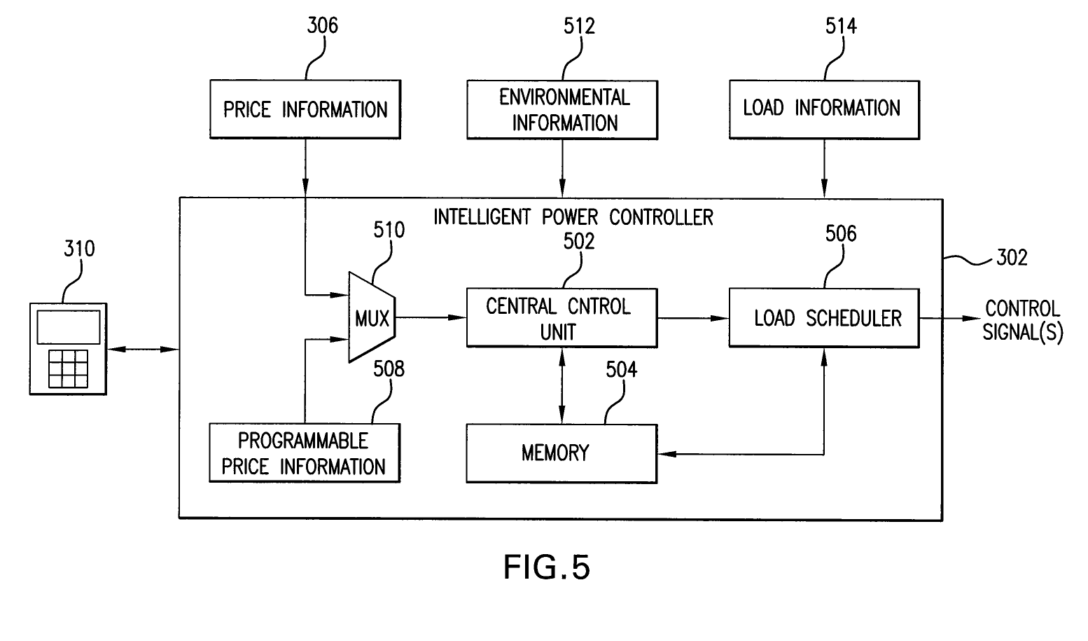

FIG. 5 is a diagram that further illustrates an example intelligent power controller 302 of an intelligent power unit 200 according to an embodiment of the present invention. As shown in FIG. 5, in an embodiment, intelligent power controller 302 includes a central control unit 502, a memory 504, a load scheduler 506, a programmable price information module 508 and a multiplexer 510.

Central control unit 502 receives input information and makes determinations about when electrical energy supplied by a utility should be stored in battery 303 and when electrical energy stored in battery 303 should be supplied to household load(s) 201 and/or sold back to the utility. In an embodiment, the input information used by central control unit 502 to make these determinations includes price information 306, environmental information 512, load information 514, and/or other information stored in memory 504. In embodiments, the price information provided to central control unit 502 can be actual, near real-time price information about the cost of generating electrical power, estimated price information about the cost of generating electrical power and/or contract price information. The environmental information can be actual or forecast weather information such as, for example, temperature information, precipitation information, cloud cover information, etc. The load information can be information about the total household load and/or information about individual loads such as, for example, a heating and air-conditioning unit, a hot water heater, etc. A more detailed description of central control unit 502 is provided below.

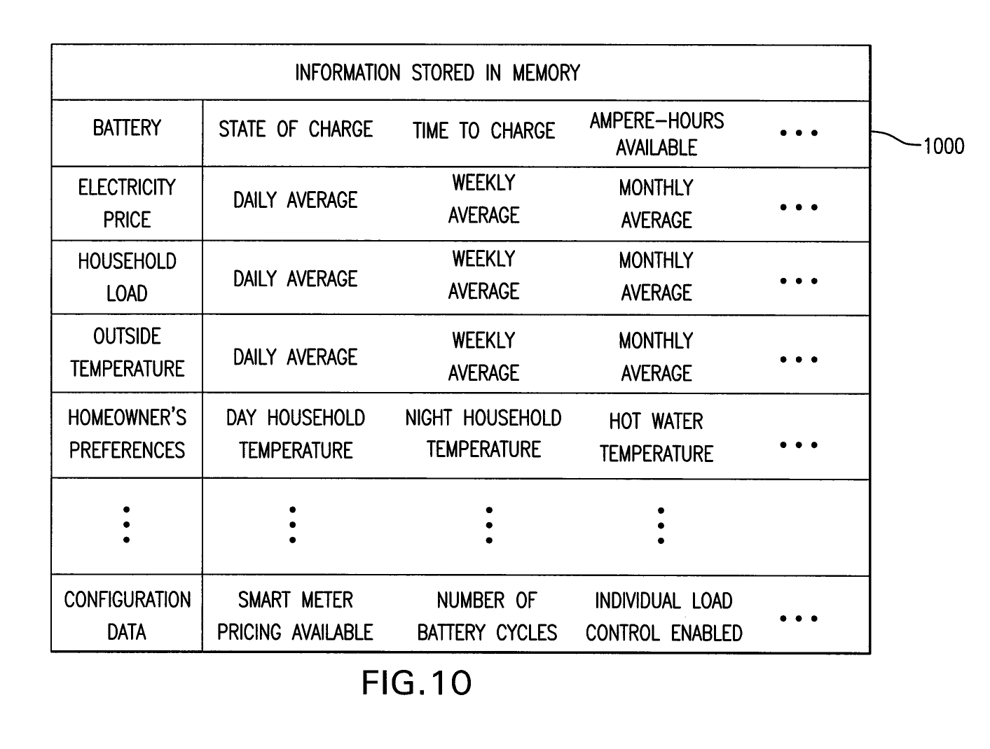

In embodiments, memory 504 is used to store a variety of information used by central control unit 502. This information includes, for example, information about battery 303, electricity price information, household load information, home owner preference information and/or configuration information about intelligent power unit 200. This information can be entered, for example, using keypad unit 310. In embodiments, memory 504 stores any information that is useful for controlling the operation of intelligent power unit 200. Additional examples of the type of information stored in memory 504 are provided below with reference to FIG. 10.

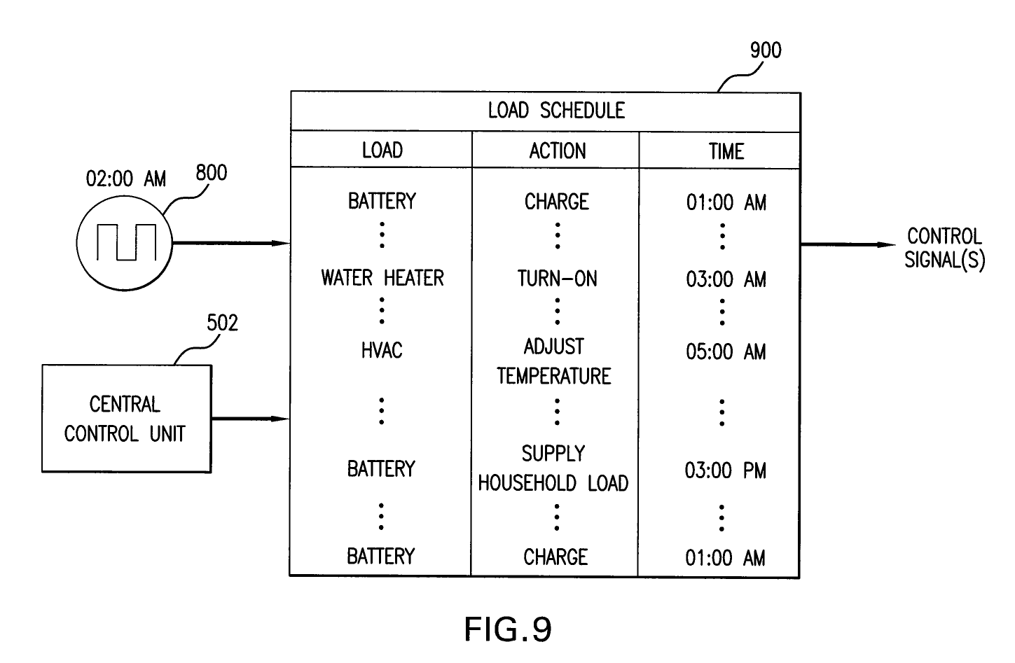

Load scheduler 506 is used to control the operation of power switches and converters 301 (see, e.g., FIG. 3A). In an embodiment, load scheduler 506 provides control signals to power switches and converters 301 that cause utility power to be rectified and stored in battery 303. Load scheduler 506 also provides control signals to power switches and converters 301 that cause electrical energy stored in battery 303 to be inverted and supplied to household load(s) 201. In one embodiment, load scheduler 506 provides multiple control signals that turn-on, turn-off and/or adjust individual loads such as, for example, a heating and air-conditioning unit, a hot water heater, a dish washer, a cloths washer, a dryer, etc. Load scheduler 506 is further described below with reference to FIG. 9.

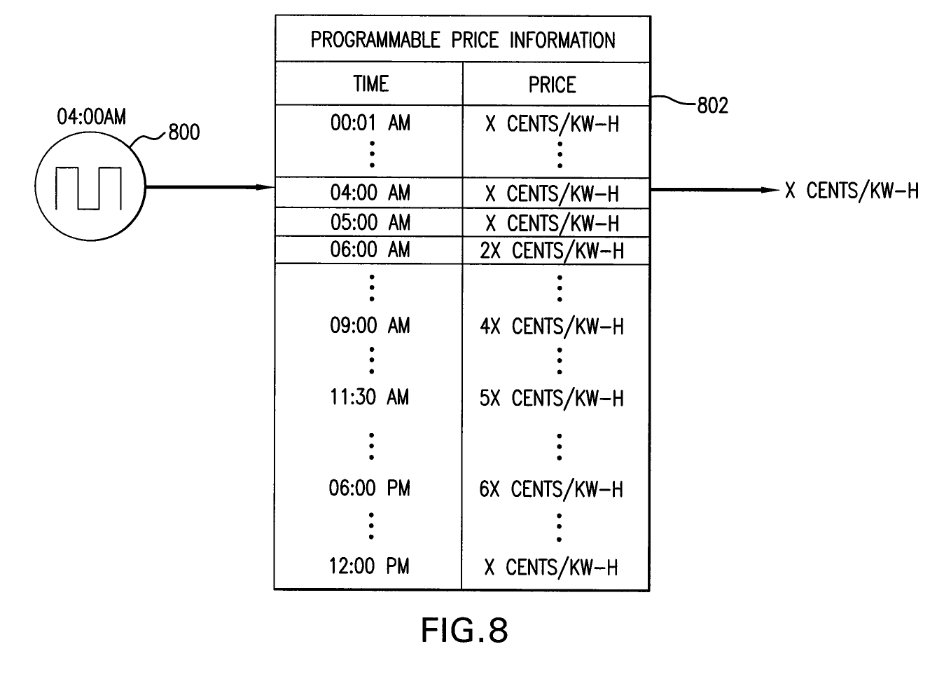

Programmable price information module 508 stores time-dependent pricing information. In an embodiment, this information is entered/programmed using keypad unit 310. Keypad unit 310 is a user interface coupled to intelligent power controller 302. In an embodiment, keypad unit 310 includes both keys/buttons for entering information and a display for displaying information. In one embodiment, intelligent power controller 302 includes a computer program that prompts a user to enter specific information such as, for example, the contract price of electricity for specific times during a day. Programmable price information module 508 is further described below with reference to FIG. 8.

Multiplexer 510 is used to select price information and provide the selected price information to central control unit 502. In embodiments, where external price information 306 is available, multiplexer 510 selects and provides this external price information to central control unit 502. If external price information 306 is not available, multiplexer 510 selects and provides price information from programmable price information module 508 to central control unit 502. This feature of intelligent power controller 502 permits intelligent power unit 200 to be used even if no price information 306 is available, for example, from a smart electric meter or via the internet.

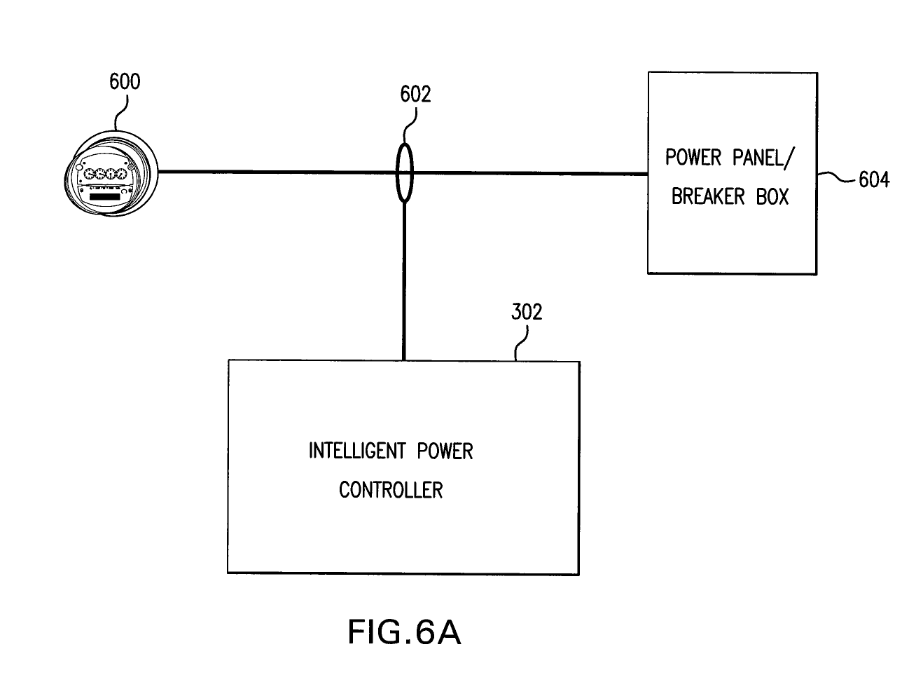

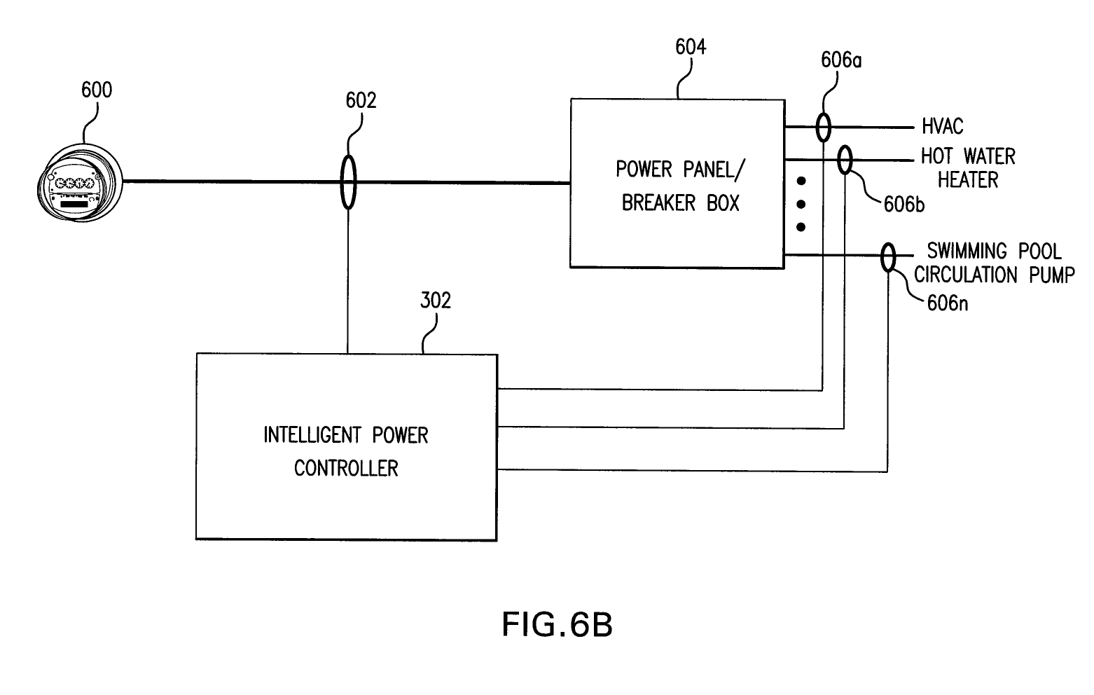

FIG. 6A is a diagram that illustrates using a current transformer 602 to provide load information to intelligent power controller 302. In an embodiment, current transformer 602 is coupled to a power line between a power meter 600 and a power panel/breaker box 604. Coupling current transformer 602 to a power line between power meter 600 and power panel/breaker box 604 enables the current transformer to be used to determine the total load of a household. This load information can be combined with a clock time stamp (see, e.g., clock 800 in FIG. 8) and stored in memory 504 to provide time-dependent load information for a household. By collecting and analyzing this information, for example, over a period of days, weeks and/or months, expected time-dependent load information can be obtained for the household and provided to central control unit 502 of intelligent power controller 302.

FIG. 6B is a diagram that illustrates using current transformers 606a-n to provide load information about individual household loads to intelligent power controller 302. As shown in FIG. 6B, in an embodiment, current transformer 606a is used to monitor a heating and air-conditioning (HVAC) unit. Current transformer 606b is used to monitor a hot water heater. Current transformer 606n is used to monitor a swimming pool circulation pump. In an embodiment, current transformers 606a-n are used in conjunction with current transform 602. Current transformer 602 is used to monitor the total household load while current transformers 606a-n are used to monitor specific individual household loads. In the embodiment shown in FIG. 6B, it is not necessary to monitor every load supplied from power panel/breaker box 604 with a current transformer 606.

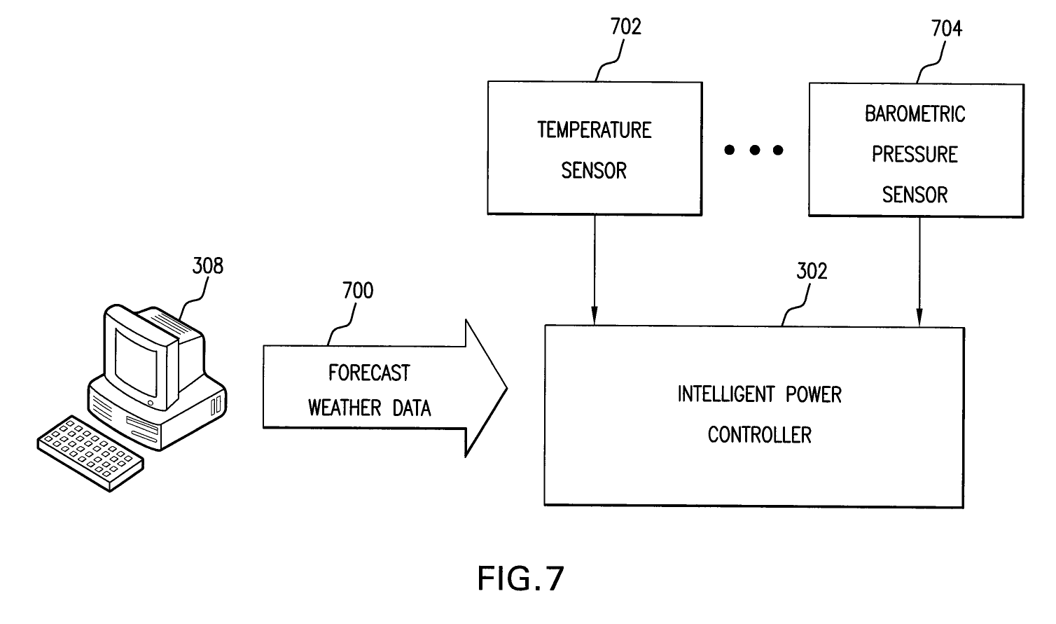

FIG. 7 is a diagram that illustrates an example of how environmental information is provided to an intelligent power controller 302 of an intelligent power unit 200. In an embodiment, this information is provided using a computer 308. Computer 308 downloads forecast weather data 700 via the Internet and transmits the forecast weather data to intelligent power controller 302. In an embodiment, real-time environmental data is provided to intelligent power controller 302 by local sensors such as, for example, a temperature sensor 702, a barometric pressure sensor 704, etc. This environmental information can be stored in memory 504 and analyzed to produce trend information. This trend information, in turn, can be used to make predictions, for example, about future environmental conditions and about how future environmental conditions will effect the price of electrical power and the household loads (e.g., if the trend data indicates that the average and/or peak temperature for the day will be hotter than normal, it can be anticipated that energy prices will be higher than normal due to an overall increased in the use of air-conditioning units, and that any given household air-conditioning unit will work longer and harder than normal and consume more electrical energy than normal).

FIG. 8 is a diagram that illustrates an example of how programmable price information is generated in a programmable price information module 508 of an intelligent power controller 302 according to an embodiment of the present invention. As shown in FIG. 8, in an embodiment, the price information is generated using a clock 800 and a programmable price information lookup table 802.

Lookup table 802 includes a number of time entries and a number of corresponding price entries. In an embodiment, the price information stored in lookup table 802 is indexed by the time information. For example, as shown in lookup table 802, the programmed/stored price of electrical power beginning a 04:00 AM is X Cents/KW-H. This price remains in effect until 06:00 AM, when the price changes from X Cents/KW-H to 2X Cents/KW-H. Thus, any clock time from 04:00 AM until 05:59 AM used to access price information in lookup table 802 will return a price of X Cents/KW-H. If a time of 06:00 AM is used to access price information in lookup table 802, the price returned will be 2X Cents/KW-H

As noted herein, in an embodiment, the time and price information stored in lookup table 802 can be entered using keypad unit 310 (see, e.g., FIG. 5). In an embodiment, the price information programmed into lookup table 802 is contract price information (e.g., the contract price that a utility will charge a customer for using energy at a specific time of day). In an embodiment, this information can be down-loaded from the Internet using a computer in communication with intelligent power controller 302.

FIG. 9 is a diagram that illustrates an example of how a load scheduler 506 of an intelligent power unit 200 operates. As shown in FIG. 9, in an embodiment load scheduler 506 maintains a load schedule list 900. In an embodiment, each entry in load schedule list 900 includes load information, action information, and time information. Other information (e.g., date information, action duration information, etc.) can also be included. This information is written to load schedule list 900 by central control unit 502 and acted on at an appropriate time by intelligent power unit 200.

To better understand the operation of load scheduler 506, consider the following example. Assume that central control unit 502 determines (e.g., at 11:00 PM on a Wednesday based on predicted price information) that battery 303 of intelligent power unit 200 should be charged beginning at 01:00 AM on Thursday. In this instance, central control unit 502 will write an entry into load schedule list 900 that the “battery” (load information) should “charge” (action information) beginning at “01:00 AM” (time information). When clock 800 outputs a time signal representative of 01:00 AM, load scheduler 506 will generate control signals that cause intelligent power unit 200 to begin charging battery 303 using utility power. This charging of battery 303 will continue, for example, until battery 303 is fully charged or until an intervening event causes the charging to be interrupted. In embodiments of the present invention, load scheduler 506 is used to schedule (e.g., turn-on, turn-off, adjust, etc.) individual household loads (e.g., a heating unit, an air-conditioning unit, a hot water heater, etc.). By controlling individual household loads, intelligent power unit 200 can minimize the overall electric energy bill of a residential customer.

FIG. 10 is a diagram that illustrates example information 1000 stored by an intelligent power controller 302 (e.g., in memory 504) of an intelligent power unit 200. In an embodiment, information 1000 can include information about the intelligent power unit battery, electricity price information, household load information, outside temperature information, information about a homeowner's preferences, intelligent power unit configuration information, etc. The information 1000 stored by intelligent power controller 302 is used, for example, as input information for calculations and/or to control the operation of intelligent power unit 200.

As shown in FIG. 10, in an embodiment, intelligent power controller 302 stores information about the intelligent power unit battery. This information can include the state of the battery's charge, the time needed to fully charge the battery, the ampere-hours available from the battery, etc. In an embodiment, the state of the battery's charge is used to determine whether battery charging is required. If battery charging is required, knowing how long it will take to charge the battery is used to identify a suitable period of relatively low power pricing during which the battery can be charge. Knowing the amount of ampere-hours available from the battery on the other hand is used, for example, to decide when to supply energy from the battery to household loads. Ideally, this is done during one or more time periods when electrical power supplied by a utility is most expensive. In order to accomplish this task, it is useful to determine not only how many ampere-hours the battery can supply, but an expected household load (e.g., in ampere-hours) during a particular period of time under consideration for using the battery and an expected cost of utility power supplied during the specific period of time under consideration.

In an embodiment, as shown in FIG. 10, intelligent power controller 302 stores information about average electricity prices (e.g., hourly averages, daily averages, weekly averages, monthly averages, etc.), average household loads, outside temperatures, etc. These average values are used, for example, to make predictions about future values and/or to identify trends. Knowing that the current electricity price is below the daily average price, for example, can be used as an indication that the price of electricity is likely to rise in the near term. Similarly, knowing that the current outside temperature is higher that the daily average or weekly average temperature can be used as an indication that the household load for the day is likely to be higher than the stored average household load due to an increase in the use of air-conditioning. Furthermore, if information about the average load of the household's air-conditioning unit is recorded and stored by intelligent power controller 302, a more accurate prediction about how much additional load will be required by the air-conditioning unit as a result of the increase in outside temperature can be made. Thus, as illustrated herein, information stored by intelligent power controller 302 is useful for making predictions about future values.

In addition to information useful for making predictions about future values, intelligent power controller 302 also stores information about a homeowner's preferences. This information can include, for example, the homeowner's preferences for a day household temperature, a night household temperature, the temperature of hot water, etc. These preference values are used by intelligent power controller 302 in its calculations to determine, for example, when certain actions can or should be taken (e.g., when the temperature setting of an HVAC unit can be adjusted, when the hot water heater can be turn-off, etc.) In an embodiment, software implemented by intelligent power controller 302 is used to satisfy the homeowner's programmed preferences while minimizing costs. This software, as well as other software used to implement various features of the present invention can be updated and/or replace remotely in embodiments of the present invention by downloading new software using commonly accepted communication protocols such as, for example, TCP/IP or another communication protocol.

As illustrated by FIG. 10, another category of information stored by intelligent power controller 302 is configuration data. In an embodiment, this data includes, for example, whether smart meter pricing is available, the number of battery charging and discharging cycles completed (e.g., a measure of expected battery life remaining), whether individual load control is enabled (e.g., whether intelligent power controller 302 is setup to turn-on and turn-off individual household appliances, the HVAC unit, the water heater), etc. The stored configuration data is used to determine, for example, what features of intelligent power unit 200 are activated/enabled.

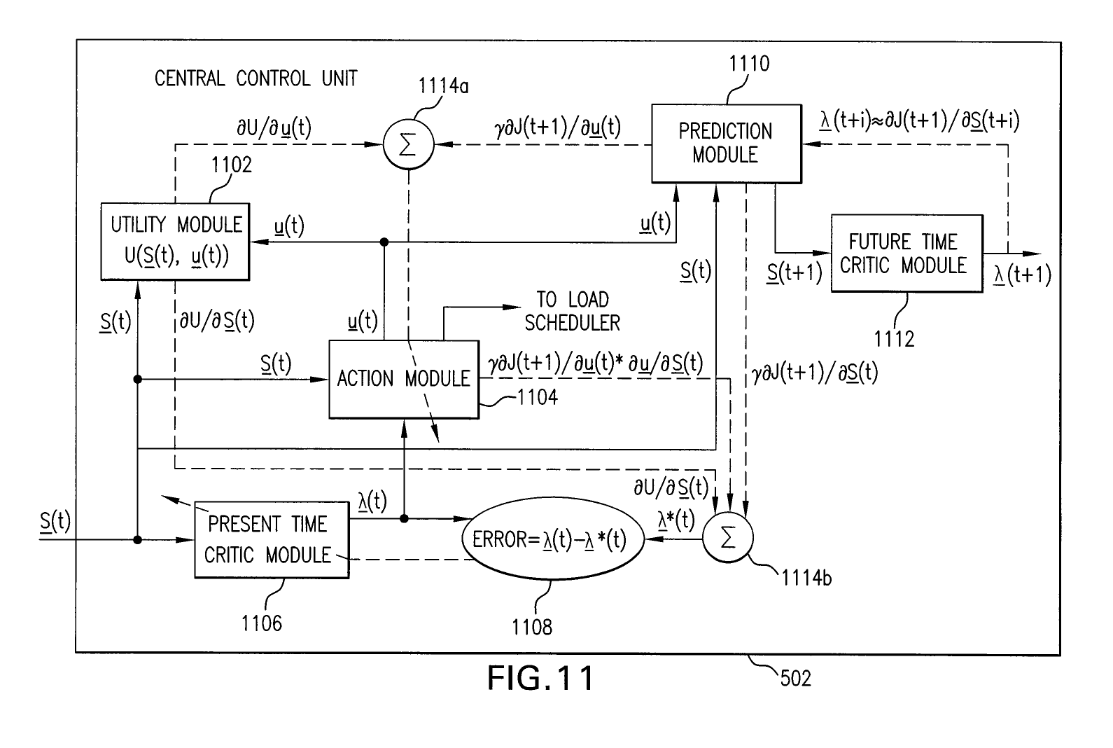

FIG. 11 is a diagram that illustrates an example central control unit 502 of an intelligent power controller 302 of an intelligent power unit 200. As shown in FIG. 11, in an embodiment central control unit 502 includes a utility module 1102, an action module 1104, a present time critic module 1106, an error module 1108, a prediction module 1110, a future time critic module 1112, and summing modules 114a and 114b.

In an embodiment, utility module 1102 represents and operates on control variables and/or parameters that are to be maximized and/or minimized over time. For example, in an embodiment, central control unit 502 can be programmed to minimize a customer's electricity bills and/or maximize money earned by selling power back to a utility. The inputs to utility module 1102 are the vector variables S(t) and u(t). S(t) is a state vector that includes both time dependent price information and time dependent load information. u(t) is a utility vector that includes time dependent control information such as, for example, a homeowner's preferences (e.g., a day household temperature, a night household temperature, a water heater temperature, etc.). The utility module operates on S(t) and u(t) to produce derivatives of these vectors with respect to time (e.g., ∂U/∂S(t) and ∂U/∂ u(t)). The derivative output ∂U/∂S(t) is provided to summing module 1114a. The derivative output ∂U/∂ u(t) is provided to summing module 1114b.

Action module 1104 is the module of central control unit 502 that generates the control information provided to load scheduler 506 (see FIG. 5). The inputs to action module 1104 are S(t) and λ(t). The vector variable λ(t) is a costate variable output by action module critic 1106. In addition to the information provided to load scheduler 506, action module 1104 outputs the utility vector u(t) and a derivative γ∂J(t+1)/∂u(t)*∂u/∂S(t), where “t+1” represents a next decision iteration/cycle time. The utility vector u(t) is provided to utility module 1102 and to prediction module 1110. The derivative γ∂J(t+1)∂u(t)*∂u/∂S(t) is provided to summing module 1114b. The arrow through action module 1104 shown in FIG. 11 indicates that the output of summing module 114a is back-propagated.

Present time critic module 1106 is used to generate and provide a vector of values (e.g., shadow prices) that are used to train action module 1104 and/or to provide value information to action module 1104. In an embodiment, present time critic module 1106 assesses the value λᵢ(t) representing the total value of changing Sᵢ(t) for a user across all future times.

In an embodiment, present time critic module 1106 operates on the variable S(t) and the output of error module 1108 to produce the costate variable λ(t). As noted herein, the costate variable λ(t) is a measure of how well central control unit 502 is performing at the present time. The costate variable λ(t) is provided to action module 1104 and to error module 1108. The arrow through present time critic module 1106 shown in FIG. 11 indicates that the output of error module 1108 is back-propagated. As shown in FIG. 11, the output of error module 1108 is equal to λ(t)−λ*(t) (i.e., the output of summing module 1114b).

Prediction module 1110 is used to predict the state of control variables and/or parameters at a future time “t+1”. For example, in an embodiment, prediction module 1110 is used to predict future values such as future electrical power prices and future household loads. The inputs to prediction module 1110 are S(t), u(t), and the derivate value output by prediction module critic 1112 (e.g., λ(t+1)≈∂J(t+1)/∂S(t+1). The outputs of prediction module 1110 are S(t+1), the derivative value γ∂J(t+1)/∂u(t), and the derivative value γ∂J(t+1)/∂S(t). S(t+1) is provided to future time critic module 1112. The derivative value γ∂J(t+1)/∂u(t) is provided to summing module 1114a. The derivative value γ∂J(t+1)/∂S(t) is provided to summing module 1114b.

Future time critic module 1112 operates on the variable S(t+1) and produces the costate variable λ(t+1). The costate variable λ(t+1) is a measure of how well central control unit 502 will be performing at a future time if specified actions are taken at the present time.

Summing module 1114a combines the output of utility module 1102 (∂U/∂u(t)) and the output of prediction module 1110 (γ∂J(t+1)/∂u(t)) and provides the resultant value to action module 1104.

Summing module 1114b combines the output of utility module 1102 (∂U/∂S(t)), the output of action module 1104 (γ∂J(t+1)/∂u(t)*∂u/∂S(t)), and the output of prediction module 1110 (γ∂J(t+1)/∂S(t)) and provides the resultant value to error module 1108.

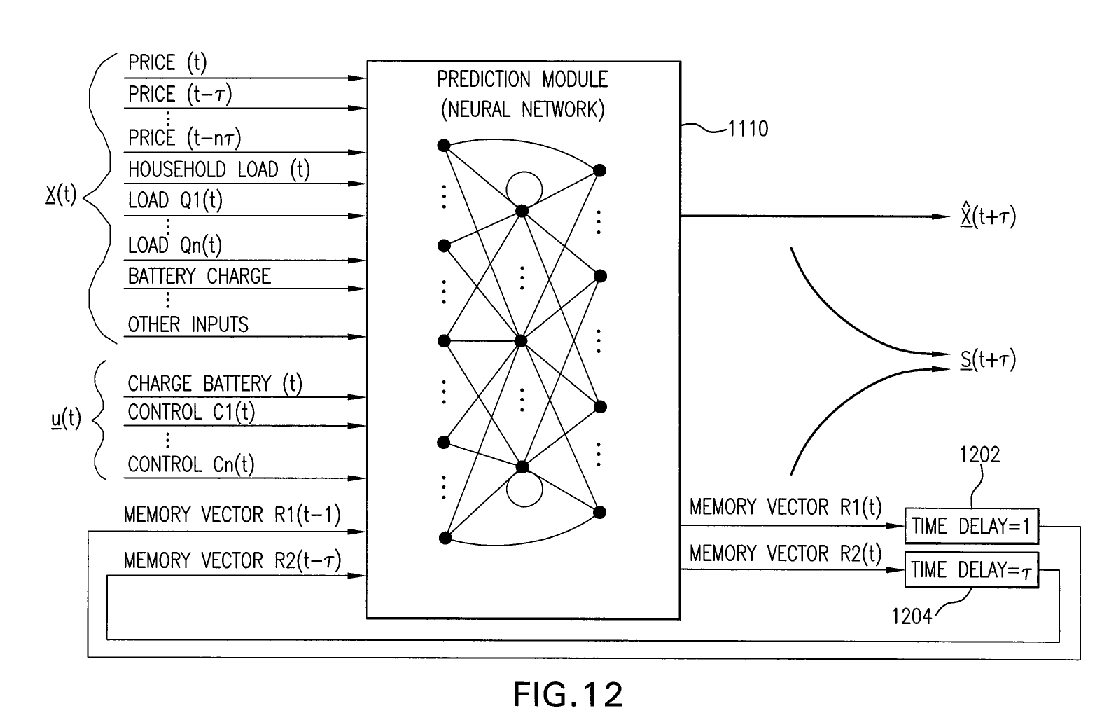

FIG. 12 is a diagram that further illustrates example prediction module 1110 of central control unit 502. As shown in FIG. 12, in an embodiment, prediction module 1110 is implemented as a neural network (e.g., either feed forward or with simultaneous recurrence). However, the present invention is not limited to using a neural network. Any differentiable system containing variables and/or parameters that can be adapted to learn a mapping from a vector of inputs to a vector of outputs, for example, with a provision to input one or more of its own outputs from one or more previous time periods, can be used to implement prediction module 1110.

In the embodiment shown in FIG. 12, prediction module 1110 receives as inputs price and load information (e.g., X(t)), control inputs (e.g., u(t)), and state memory values (e.g., memory vectors R1(t−1) and R2(t−τ), where τ is a time interval between price information updates). The state vector S(t) is a combination of the variables X(t) and the memory vectors R1(t−1) and R2(t−τ).

As shown in FIG. 12, in order to make more accurate predictions at later time periods and/or to adapt to changing conditions, prediction module 1110 outputs one or more memory vectors R. The loops shown in prediction module 1110 represent simultaneous recurrence, and not time-lag recurrence. The design of prediction module 1110 can include, for example, instances where individual neurons receive as inputs their individual outputs, but such memory variables should also be available as part of a memory vector R so that the output of the entire network is available to action module 1104 and future time critic module 1112.

It is important to note herein, that in a situation where intelligent power unit 200 is used to sell power back to a utility (e.g., from the battery, solar panels or a windmill connected to intelligent power unit 200), the phase of the inverter circuit output should closely match the phase of the utility power. To facilitate this, an inverter phase variable is included in intelligent power controller 302 that is used to control the phase output of the inverter. The inverter phase variable is used to detect/predict phase mismatches and correct any error in phase.

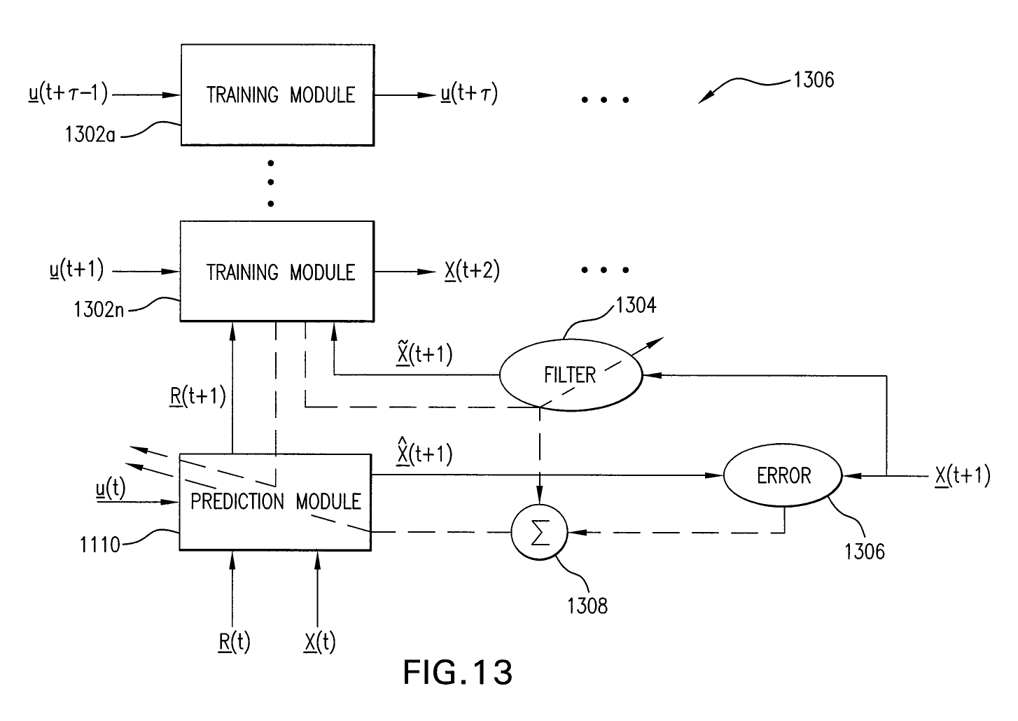

FIG. 13 is a diagram that illustrates an example training circuit 1300 for a prediction module 1110 of a central control unit 502. As shown in FIG. 13, in an embodiment training circuit 1300 includes a plurality of training modules 1302a-n, a filter 1304, an error module 1306, and a summing module 1308 combined as shown in FIG. 13.

As shown in FIG. 13, in an embodiment, the training of prediction module 1110 is based on a weight-based error measure. Any of several methods can be used to adapt the weights such as, for example, ordinary gradient descent, an adaptive learning rate algorithm, distributed extended Kalman filtering, etc. (see, e.g., Chapter 3 of the Handbook of Intelligent Control; the Handbook of Intelligent Control: Neural, Fuzzy, and Adaptive Approaches, edited by David A. White and Donald A. Sofge, Van Nostrand Reinhold, N.Y. (1992), is incorporated herein by reference in its entirety). In an embodiment, the training is based on gradients of the total error measure, propagated by backpropagation. This can be by backpropagation through time, as shown in FIG. 13, or by use of an error critic approach (see, e.g., Chapter 13 of the Handbook of Intelligent Control). The training of prediction module 1110 can also be based on other error measures (e.g., square error can be used). In one embodiment, a likelihood function that is a function of square error and of weights in prediction module 1110 itself is used.

In an embodiment, training circuit 1300 is used to train prediction module 1110 before it is initially placed in service. In some embodiments, training circuit 1300 is used periodically to train prediction module 1110 while it is on-line (e.g., operating).

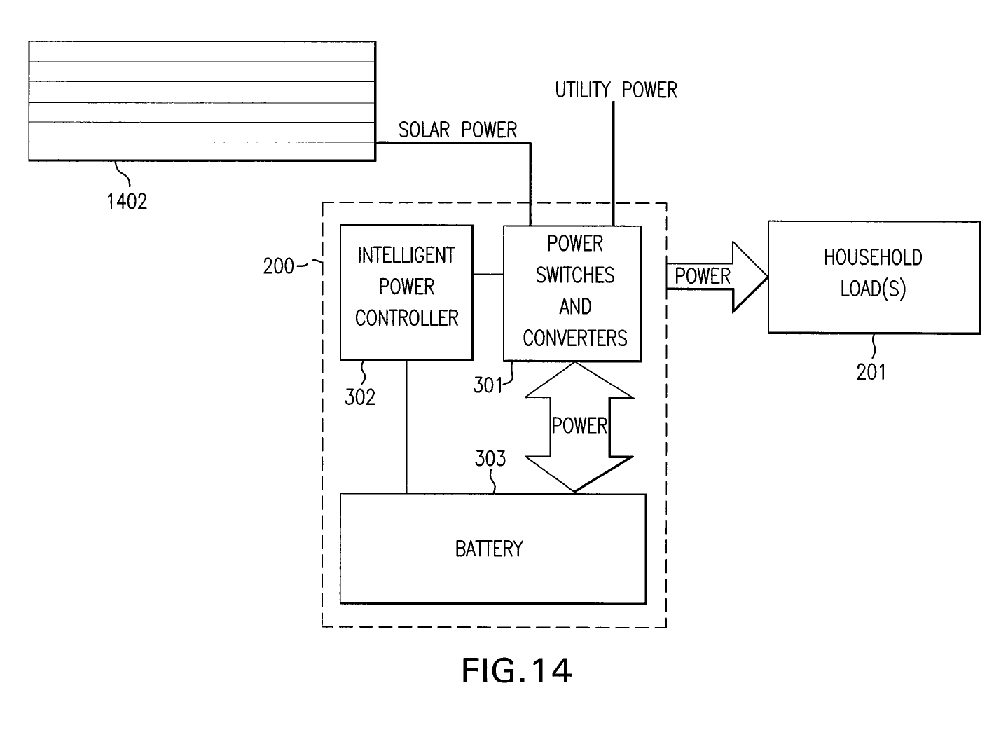

FIG. 14 is a diagram that illustrates using an intelligent power unit 200 with solar energy panels 1402. As shown in FIG. 14, intelligent power unit 200 includes power switches and converters 301, an intelligent power controller 302, and a battery 303. These components operate as describe above. Solar energy panels 1402 can be any commercially available solar energy panels.

When intelligent power unit 200 is coupled to solar energy panels 1402, intelligent power unit 200 has an additional flexibility in that it can charge battery 303 or power household load(s) 201 with power produced by solar energy panels 1402. In an embodiment, the power produced by solar energy panels 1402 is assigned a cost of zero cents/KW-H. This is done so that intelligent power controller 302 will prioritize using power produced by solar energy panels 1402 before using power supplied by a utility.

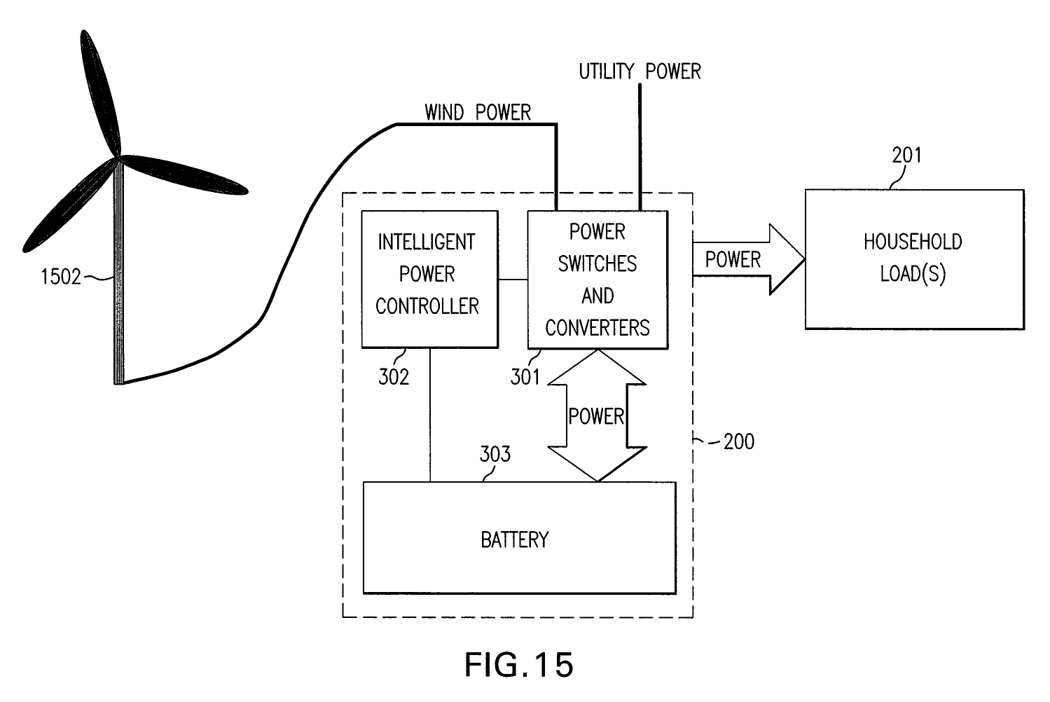

FIG. 15 is a diagram that illustrates using an intelligent power unit 200 with a windmill 1502. As shown in FIG. 15, intelligent power unit 200 includes power switches and converters 301, an intelligent power controller 302, and a battery 303 that operate as describe above. Windmill 1502 can be any commercially available windmill.

When intelligent power unit 200 is coupled to windmill 1502, intelligent power unit 200 has the additional flexibility of being able to charge battery 303 or power household load(s) 201 with power produced by windmill 1502. In an embodiment, the power produced by windmill 1502 is assigned a cost of zero cents/KW-H so that intelligent power controller 302 will prioritize using power produced by windmill 1502 before using power supplied by a utility.

As will be understood by persons skilled in the relevant art(s) given the description herein, various features of the present invention can be implemented using processing hardware, firmware, software and/or combinations thereof such as, for example, application specific integrated circuits (ASICs). Implementation of these features using hardware, firmware and/or software will be apparent to a person skilled in the relevant art. Furthermore, while various embodiments of the present invention have been described above, it should be understood that they have been presented by way of example, and not limitation. It will be apparent to persons skilled in the relevant art(s) that various changes can be made therein without departing from the scope of the invention. For example, although the present invention is described above with references to residential electric utility customers, the present invention is equally well suited for use by commercial customers such as small business owners, stores, business offices, factories, etc.

It should be appreciated that the detailed description of the present invention provided herein, and not the summary and abstract sections, is intended to be used to interpret the claims. The summary and abstract sections may set forth one or more but not all exemplary embodiments of the present invention as contemplated by the inventors.

What is claimed is:

1. A power unit, comprising:
a power switch; and
a control unit coupled to the power switch,
wherein the control unit receives price information and operates the power switch based on the price information.

2. The power unit of claim 1, wherein the price information is one of actual price information regarding cost to generate electrical power, estimated price information, and contract price information.

3. The power unit of claim 1, wherein the price information is received from one of an electrical power meter, a computer, and a keypad.

4. The power unit of claim 1, wherein the control unit receives load information and operates the power switch based on the load information.

5. The power unit of claim 4, wherein the control unit receives load information from a current transformer.

6. The power unit of claim 1, wherein the control unit receives environmental information and operates the power switch based on the environmental information.

7. The power unit of claim 6, wherein the control unit receives environmental information from one of a computer and a sensor.

8. The power unit of claim 1, wherein the control unit includes a load scheduler.

9. The power unit of claim 8, wherein the load scheduler provides a control signal to one of a heating unit, an air-conditioning unit, and a water heater.

10. The power unit of claim 1, wherein the control unit includes programmable price information.

11. The power unit of claim 1, further comprising:
a battery coupled to the power switch.

12. The power unit of claim 1, further comprising:
a keypad coupled to the control unit.

13. An control unit, comprising:
a prediction module; and
an action module coupled to the prediction module,
wherein the prediction module operates on price information and generates a control value based on the price information, and the action module generates an output value that is used to control operation of a power switch.

14. The control unit of claim 13, wherein the price information is one of actual price information regarding cost to generate electrical power, estimated price information, and contract price information.

15. The control unit of claim 13, wherein the prediction module receives load information and uses a neural network to combine the load information and the price information and generate the control value.

16. The control unit of claim 13, wherein the prediction module receives environmental information and uses a neural network to combine the environmental information and the price information and generate the control value.

17. The control unit of claim 13, wherein the action module generate a value that is used to control one of a heating unit, an air-conditioning unit, and a water heater.

18. A power unit, comprising:
a battery; and
a control unit coupled to the battery,
wherein the control unit receives price information and controls the charging of the battery based on the price information.

19. The power unit of claim 18, further comprising:
a solar panel coupled to the battery.

20. The power unit of claim 18, further comprising:
a windmill coupled to the battery.
